(19) United States
(12) Patent Application Publication
(10) Pub. No.: US 2008/0038867 A1
(43) Pub. Date: Feb. 14, 2008

(54) METHOD FOR MANUFACTURING A THIN FILM TRANSISTOR ARRAY PANEL

(75) Inventors: Jung-Han SHIN, Yongin-si (KR); Bo-Sung KIM, Seoul (KR); Seong-sik SHIN, Seongnam-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/745,722

(22) Filed: May 8, 2007

(30) Foreign Application Priority Data
Aug. 8, 2006 (KR) 10-2006-0074638

(51) Int. Cl. H01L 51/40

(52) U.S. Cl. 438/99; 257/E21.372

(57) ABSTRACT

A method for manufacturing a thin film transistor array panel includes forming a gate electrode, forming a source electrode and a drain electrode opposing each other and separated from each other on the gate electrode, forming a gate insulator on the gate electrode, forming an organic semiconductor on the gate insulator, and forming a passivation member covering the organic semiconductor, wherein the source and drain electrodes contact the organic semiconductor, and an ink-jet printing process is used to form at least two among the gate insulator, the organic semiconductor, and the passivation member, and wherein a mixed solvent including at least two among a gate insulator material, an organic semiconductor material, and a passivation member material is sprayed in the ink-jet printing process.

This application claims priority to Korean Patent Application No. 10-2006-0074638, filed on Aug. 8, 2006 and all the benefits accruing therefrom under 35 U.S.C. §119, the contents of which in its entirety are herein incorporated by reference.

### BACKGROUND OF THE INVENTION

(a) Field of the Invention

The present invention relates to a method for manufacturing a thin film transistor (“TFT”) array panel. More particularly, the present invention relates to a method for manufacturing a TFT array panel having an organic TFT.

(b) Description of the Related Art

Generally, a flat panel display, such as a liquid crystal display (“LCD”), an organic light emitting diode (“OLED”) display, and an electrophoretic display, includes a pair of electric-field generating electrodes and an electro-optical active layer disposed there between. The LCD includes a liquid crystal layer as the electro-optical active layer, and the OLED display includes an organic light emitting layer as the electro-optical active layer.

One electrode of the pair of field generating electrodes is usually coupled with a switching element to receive electrical signals, and the electro-optical active layer converts the electrical signals into optical signals to display images.

The switching element for the flat panel display includes a thin film transistor (“TFT”) having three terminals, and gate lines transmitting control signals for controlling the TFTs and data lines transmitting data signals to be supplied to pixel electrodes through the TFTs are also provided in the flat panel display.

Among the TFTs, organic thin film transistors (“OTFTs”) are being vigorously developed. An OTFT includes an organic semiconductor instead of an inorganic semiconductor such as silicon (“Si”).

Because the OTFT may be manufactured by a solution process such as ink-jet printing, it may be easily adapted to a flat panel display of a large size, which may not be manufactured by a deposition process. Also, because the organic material is made of patterns such as a fiber or a film, the OTFT is used as the core element of a flexible display device.

In an ink-jet printing process, a head for inkjet printing is moved and an organic solvent is jetted to form a plurality of organic films such as the organic semiconductor layer and an insulating layer in regions defined by partitions.

However, because a plurality of ink-jet heads are needed to form a plurality of organic films such as the organic semiconductor layer and an insulating layer, the equipment costs may be increased. Also, even if the plurality of organic films are formed by using the same ink-jet head, cleaning processes for cleaning the ink-jet heads for each organic film are needed when replacing the inks for each organic film, and test processes are needed to optimize the spray condition for each ink. Accordingly, the process cost and the process time are increased.

### BRIEF SUMMARY OF THE INVENTION

The present invention provides a method for manufacturing a thin film transistor (“TFT”) array panel for minimizing process cost and process time when forming organic films with ink-jet printing.

According to exemplary embodiments of the present invention, a method for manufacturing a TFT array panel includes forming a gate electrode, forming a source electrode and a drain electrode opposing each other and separated from each other on the gate electrode, forming a gate insulator on the gate electrode, forming an organic semiconductor on the gate insulator, and forming a passivation member covering the organic semiconductor. The source and the drain electrodes contact the organic semiconductor, and an ink-jet printing process is used to form at least two among the gate insulator, the organic semiconductor, and the passivation member, and a mixed solvent including at least two among a gate insulator material, an organic semiconductor material, and a passivation member material is sprayed in the ink-jet printing process.

The mixed solvent may be insoluble, and it may be manufactured by melting at least two among the gate insulator material, the organic semiconductor material, and the passivation member material in a solvent. The mixed solvent may include a surfactant.

The method may further include drying the mixed solvent to separate each layer after spraying the mixed solvent.

The organic semiconductor material may be made of, or from precursors of, pentacene, or is made of, or from derivatives of, tetrabenzoporphyrin, polyphenlenevinylene, polyfluorene, polythienylenevinylene, polythiophene, polythienothiophene, polyarylamine, and phthalocyanine, or is made of poly 3-hexylthiophene, metallized phthalocyanine or halogenated derivatives thereof, perylene tetracarboxylic dianhydride (“PTCDA”), naphthalene tetracarboxylic dianhydride (“NTCDA”), or their imide derivatives, or is made of perylene, coronene, or derivatives thereof with a substituent.

The gate insulator material may be made of, or from derivatives of, polyacryl, polystyrene, polyimide, polyvinyl alcohol, parylene, perfluorocyclobutane, perfluorovinylether, or benzocyclobutane (“BCB”).

The passivation member may be made of an insulating material such as are normally used, such as a fluorine hydrocarbon compound, polyvinyl alcohol (“PVA”), polyvinyl pyrrolidone (“PVP”), polyethylene glycol, and derivatives thereof.

The method may further include forming a self assembly monolayer between the gate insulator and the organic semiconductor, wherein the self assembly monolayer is formed by an ink-jet printing process. A mixed solvent including at least two among the gate insulator material, the organic semiconductor material, and the self assembly monolayer material is sprayed in the ink-jet printing process.

The self assembly monolayer material may include one selected from 4-methoxybenzoic acid, 4-chlorobenzoyl chloride, 4-chlorobenzenesulfonyl chloride, 4-chlorophenyl dichlorophosphate, 4-fluorobenzenesulfonyl chloride, 2-bromo-4,6-difluorobenzene sulfonyl chloride, and 3-chloro-4-fluorobenzene sulfonyl chloride.

According to other exemplary embodiments of the present invention, a method for manufacturing a TFT array panel includes forming a source electrode and a drain electrode opposing each other and separated from each other, forming an organic semiconductor island on and between the source and drain electrodes and forming a gate insulator on the organic semiconductor island using an ink-jet printing process to form the organic semiconductor island and the gate insulator, wherein a mixed solvent including both gate insulator material and organic semiconductor material is sprayed in the ink-jet printing process on and between the source and drain electrodes, and forming a gate electrode on the gate insulator.

The method may further include drying the mixed solvent subsequent the ink-jet printing process to separate the gate insulator from the organic semiconductor island.

According to still other exemplary embodiments of the present invention, a method for manufacturing a TFT array panel, where the TFT array panel includes a plurality of thin films including a gate insulator, an organic semiconductor, and a passivation member, includes forming at least two of the plurality of thin films simultaneously using an ink-jet printing process, wherein a mixed solvent including at least two among a gate insulator material, an organic semiconductor material, and a passivation member material is sprayed in the ink-jet printing process.

At least two of the plurality of thin films simultaneously formed may include the organic semiconductor and the passivation member, and the method may further include drying the mixed solvent subsequent the ink-jet printing process to separate the organic semiconductor from the passivation member.

At least two of the plurality of thin films simultaneously formed may include the organic semiconductor and the gate insulator, and the method may further include drying the mixed solvent subsequent the ink-jet printing process to separate the organic semiconductor from the gate insulator.

Spraying the mixed solvent in the inkjet. printing process may include spraying the mixed solvent on and between source and drain electrodes of the TFT array panel.

### BRIEF DESCRIPTION OF THE DRAWINGS

The present invention will become more apparent by describing exemplary embodiments thereof in detail with reference to the accompanying drawings, in which:

FIG. 1 is a layout view of an exemplary organic thin film transistor (“TFT”) array panel according to an exemplary embodiment of the present invention;

FIG. 2 is a sectional view of the exemplary organic TFT array panel shown in FIG. 1 taken along line II-II;

FIGS. 3, 5, 7, 9, 11 and 13 are layout views of the exemplary organic TFT array panel shown in FIGS. 1 and 2 during intermediate steps of an exemplary manufacturing method thereof according to an exemplary embodiment of the present invention;

FIG. 4 is a sectional view of the exemplary TFT array panel shown in FIG. 3 taken along line IV-IV;

FIG. 6 is a sectional view of the exemplary TFT array panel shown in FIG. 5 taken along line VI-VI;

FIG. 8 is a sectional view of the exemplary TFT array panel shown in FIG. 7 taken along line VIII-VIII;

FIG. 10 is a sectional view of the exemplary TFT array panel shown in FIG. 9 taken along line X-X;

FIG. 12 is a sectional view of the exemplary TFT array panel shown in FIG. 11 taken along line XII-XII;

FIG. 14 is a sectional view of the exemplary TFT array panel shown in FIG. 13 taken along line XIV-XIV;

FIG. 15 is a layout view of an exemplary organic TFT array panel according to another exemplary embodiment of the present invention; and

FIG. 16 is a sectional view of the exemplary organic TFT array panel shown in FIG. 15 taken along line XVI-XVI.

### DETAILED DESCRIPTION OF THE INVENTION

The present invention is described in detail herein with reference to the accompanying drawings, in which preferred and exemplary embodiments of the invention are shown. This invention may, however, be embodied in many different forms and should not be construed as limited to the embodiments set forth herein. In the drawings, the thickness of layers and regions are exaggerated for clarity, and like numerals refer to like elements throughout.

When an element such as a layer, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

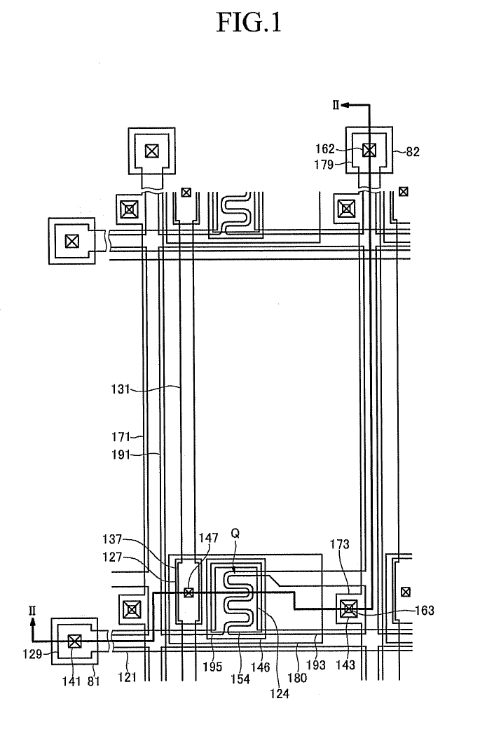

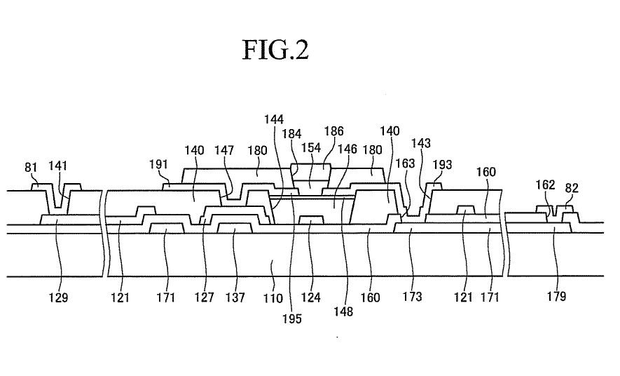

An organic thin film transistor (“TFT”) array panel according to an exemplary embodiment of the present invention will be described in detail with reference to FIGS. 1 and 2.

FIG. 1 is a layout view of an exemplary organic TFT array panel according to an exemplary embodiment of the present invention, and FIG. 2 is a sectional view of the organic TFT shown in FIG. 1 taken along line II-II.

A plurality of data lines 171 and a plurality of storage electrode lines 131 are formed on an insulating substrate 110 made of a material such as transparent glass, silicone, or plastic.

The data lines 171 transmit data signals and extend substantially parallel to each other in a longitudinal direction. Each data line 171 includes a plurality of projections 173 protruded aside towards an adjacent data line 171, and an end portion 179 having a large area for contact with another layer or an external driving circuit. A data driving circuit (not shown) for generating data signals to be transmitted by the data lines 171 may be mounted on a flexible printed circuit (“FPC”) film (not shown), which may be attached to the substrate 110, directly mounted on the substrate 110, or integrated with the substrate 110. The data lines 171 may extend to connect to a driving circuit that may be integrated with the substrate 110.

The storage electrode lines 131 transmit a predetermined voltage such as a common voltage, and extend in the longitudinal direction substantially parallel to each other and the data lines 171. Each storage electrode line 131 is disposed between two adjacent data lines 171 and may be closer to the left one of the two data lines 171, and includes a plurality of storage electrodes 137 extended to the sides of the storage electrode lines 131. However, the storage electrode lines 131 may have various shapes and arrangements.

The data lines 171 and storage electrode lines 131 are preferably made of a metal including aluminum Al or an Al alloy, silver Ag or an Ag alloy, gold Au or an Au alloy, copper Cu or a Cu alloy, molybdenum Mo or a Mo alloy, chromium Cr, tantalum Ta, or titanium Ti. The data lines 171 and the storage electrode lines 131 may have a multi-layered structure including two conductive films (not shown) having different physical characteristics.

The lateral sides of the data lines 171 and the storage electrode lines 131 are inclined relative to a surface of the substrate 110, and the inclination angle thereof ranges from about 30 to about 80 degrees.

A lower interlayer insulating layer 160 is formed on the data lines 171 and storage electrode lines 131 and on the exposed portions of the insulating substrate 110. The lower interlayer insulating layer 160 may be made of an inorganic insulator such as silicon nitride (SiNx) and silicon oxide (SiOx), or an organic insulating material. It is preferable that the thickness of the lower interlayer insulating layer 160 is in the range of about 2000 to 5000 angstroms.

The lower interlayer insulating layer 160 has a plurality of contact holes 162 exposing the end portions 179 of the data lines 171, and a plurality of contact holes 163 exposing the projections 173 of the data lines 171.

A plurality of gate lines 121 and a plurality of storage capacitor conductors 127 are formed on the lower interlayer insulating layer 160.

The gate lines 121 transmit gate signals and extend substantially parallel to each other in a transverse direction, substantially perpendicular to the longitudinal direction. Each of the gate lines 121 intersects the data lines 171 and the storage electrode lines 131 and includes a plurality of gate electrodes 124 projecting upward towards an adjacent gate line 121, and an end portion 129 having a large area for contact with another layer or an external driving circuit. A gate driving circuit (not shown) for generating the gate signals to be transmitted by the gate lines 121 may be mounted on an FPC film (not shown), which may be attached to the substrate 110, directly mounted on the substrate 110, or integrated with the substrate 110. The gate lines 121 may extend to connect to a driving circuit that may be integrated with the substrate 110.

The storage capacitor conductors 127 are separated from the gate lines 121 and overlap the storage electrodes 137.

The gate lines 121 and the storage capacitor conductors 127 may be made of a conductor material having low resistivity such as that of the data lines 171 and the storage electrode lines 131.

The lateral sides of the gate lines 121 and the storage capacitor conductors 127 are inclined relative to a surface of the substrate 110, and their inclination angles range from about 30 to about 80 degrees.

An upper interlayer insulating layer 140 is formed on the gate lines 121 and the storage capacitor conductors 127 and on the exposed portions of the lower interlayer insulating layer 160. The upper interlayer insulating layer 140 may be made of a material that may be formed by a solvent process, such as a photosensitive organic material. It is preferable that the thickness of the upper interlayer insulating layer 140 is in the range of about 5000 angstroms to 4 microns.

The portion of the upper interlayer insulating layer 140 neighboring the end portions 179 of the data lines 171 is removed to prevent poor adhesion between the upper interlayer insulating layer 140 and the lower interlayer insulating layer 160 and to effectively connect the end portion 179 of the data line 171 to the external circuit while reducing the thickness of the interlayer insulating layers 140, 160.

The upper interlayer insulating layer 140 has a plurality of openings 144 exposing the gate electrodes 124, a plurality of contact holes 141 exposing the end portions 129 of the gate lines 121, a plurality of contact holes 143 exposing the projections 173 of the data lines 171 through the contact holes 163, and a plurality of contact holes 147 exposing the storage capacitor conductors 127.

A plurality of gate insulators 146 are formed in the openings 144 of the upper interlayer insulating layer 140. The gate insulators 146 cover the gate electrodes 124, and may further cover portions of the lower interlayer insulating layer 160 surrounding the gate electrode 124 within the openings 144, and the thickness of the gate insulators 146 is in the range of about 1000 to 10,000 angstroms. Because the side walls of the openings 144 are higher than the thiclness of the gate insulators 146, the upper interlayer insulating layer 140 is banked, and it is preferable that the openings 144 have sufficient size for the gate insulators 146 to have flat surfaces.

The gate insulators 146 are preferably made of, or from derivatives of, polyacryl, polystyrene, polyimide, polyvinyl alcohol, parylene, perfluorocyclobutane, perfluorovinylether, or benzocyclobutane (BCB). A self assembly monolayer 148, as will be further described below, may further be formed on each gate insulator 146 within the openings 144.

A plurality of source electrodes 193, a plurality of pixel electrodes 191, and a plurality of contact assistants 81 and 82 are formed on the upper interlayer insulating layer 140 and the gate insulators 146. They are preferably made of indium tin oxide (“ITO”) or indium zinc oxide (“IZO”), and may have thicknesses in the range of about 300 to 800 angstroms.

The source electrodes 193 are electrically connected to the projections 173 of the data lines 171 through the contact holes 143 and 163, and are extended to the upper portion of the gate electrodes 124 to overlap one side of the gate electrodes 124.

Each pixel electrode 191 includes a portion 195 disposed opposite a source electrode 193 with respect to a gate electrode 124. This portion of the pixel electrode 191 is hereinafter referred to as the drain electrode 195, and is connected to a storage capacitor conductor 127 through the contact hole 147.

The pixel electrodes 191 overlap the gate lines 121 and the data lines 171 to increase the aperture ratio.

The drain electrodes 195 and the source electrodes 193 may have serpentine edges that face each other. The edges may be separated from each other by a distance that remains substantially constant for each pair of drain-source electrodes 195, 193.

The contact assistants 81 and 82 are connected to the end portions 129 and 179 of the gate lines 121 and the data lines 171 through the contact holes 141 and 162. The contact assistants 81 and 82 protect the end portions 129 and 179, and enhance the adhesion between the end portions 129 and 179 and external devices.

A plurality of banks 180 are formed on the source electrodes 193, the pixel electrodes 191, and the upper interlayer insulating layer 140. The banks 180 have a plurality of openings 184 disposed on the gate electrodes 124 and the openings 144 of the upper interlayer insulating layer 140 for exposing portions of the source electrodes 193 and the drain electrodes 195, and the portions of the gate insulators 146 therebetween.

The banks 180 are preferably made of a photosensitive organic material that may be formed by a solvent process, and has a thickness of about 5000 angstroms to 4 microns. The openings 184 are smaller than the openings 144 of the upper interlayer insulating layer 140 such that the banks 180 are solidly fixed to the gate insulators 146 to prevent them from lifting, and penetration of the chemical solvent may be prevented in the manufacturing process.

A plurality of organic semiconductor islands 154 are placed in the openings 184 of the banks 180. The organic semiconductor islands 154 are disposed so as to overlap the gate electrodes 124 and contact the source electrodes 193 and the drain electrodes 195. Because the height of the organic semiconductor islands 154 is smaller than that of the banks 180, the organic semiconductor islands 154 are completely contained by the banks 180. Since the lateral surfaces of the organic semiconductor islands 154 are not exposed, chemicals used in later process steps are prevented from infiltrating the organic semiconductor islands 154.

The organic semiconductor islands 154 may include a high molecular compound or a low molecular compound, which is soluble in an aqueous solution or organic solvent. In this case, the organic semiconductor islands 154 can be formed by (inkjet) printing, as will be further described below.

The organic semiconductor islands 154 may be made of, or from precursors, of pentacene. Alternatively, the organic semiconductor islands 154 may be made of, or from derivatives of, tetrabenzoporphyrin, polyphenlenevinylene, polyfluorene, polythienylenevinylene, polythiophene, polythienothiophene, polyarylamine, or phthalocyanine.

The organic semiconductor islands 154 may be made of poly 3-hexylthiophene, metallized phthalocyanine or halogenated derivatives thereof, perylene tetracarboxylic dianhydride (“PTCDA”), naphthalene tetracarboxylic dianhydride (“NTCDA”), or their imide derivatives. Alternatively, the organic semiconductor islands 154 may be made of perylene, coronene, or derivatives thereof with a substituent.

A plurality of self assembly monolayers 148 are formed between the organic semiconductor islands 154 and the gate insulators 146 to increase the adhesion therebetween and surface characteristics.

The self assembly monolayers 148 may be made of one selected from 4-methoxybenzoic acid, 4-chlorobenzoyl chloride, 4-chlorobenzenesulfonyl chloride, 4-chlorophenyl dichlorophosphate, 4-fluorobenzenesulfonyl chloride, 2-bromo-4,6-difluorobenzene sulfonyl chloride, and 3-chloro-4-fluorobenzene sulfonyl chloride.

The self assembly monolayers 148 may be formed between the organic semiconductor islands 154 and the source electrodes 193 or drain electrodes 195 to decrease the contact resistance therebetween.

A plurality of passivation members 186 are formed within the openings 184 and on the organic semiconductor islands 154, and they may have a flat top surface. The passivation members 186 are preferably made of an insulating material such as a fluorine hydrocarbon compound, polyvinyl alcohol (“PVA”), polyvinyl pyrrolidone (“PVP”), polyethylene glycol, and derivatives thereof. The passivation members 186 protect the organic semiconductor islands 154 from being damaged by external heat, plasma, or chemical materials in the manufacturing process.

A gate electrode 124, a source electrode 193, a drain electrode 195, and an organic semiconductor island 154 form an organic TFT Q. The TFT Q has a channel formed in the organic semiconductor island 154 disposed between the source electrode 193 and the drain electrode 195.

The pixel electrodes 191 receive data voltages from the organic TFT Q via the data lines 171 and generate an electric field in conjunction with a common electrode (not shown) of an opposing display panel (not shown) supplied with a common voltage, which determines the orientations of liquid crystal molecules (not shown) in a liquid crystal layer (not shown) disposed between the pixel electrodes 191 and the common electrode. A pixel electrode 191 and the common electrode form a capacitor referred to as a “liquid crystal capacitor,” which stores applied voltages even after the organic TFT turns off.

An additional capacitor called a “storage capacitor”, which is connected in parallel to the liquid crystal capacitor, is provided for enhancing the voltage storing capacity. The storage capacitors are implemented by overlapping the pixel electrodes 191 and the storage capacitor conductors 127 connected thereto with the storage electrode lines 131 including the storage electrodes 137.

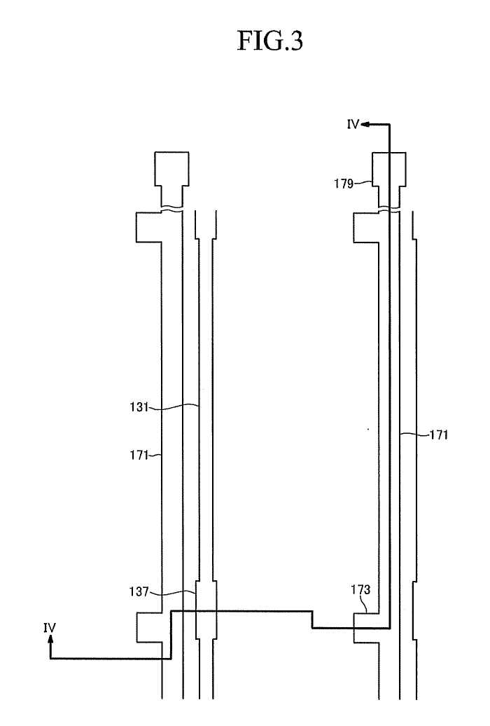

Now, an exemplary method of manufacturing the exemplary LCD shown in FIGS. 1 and 2 according to an exemplary embodiment of the present invention will be described in detail with reference to FIGS. 3 to 12.

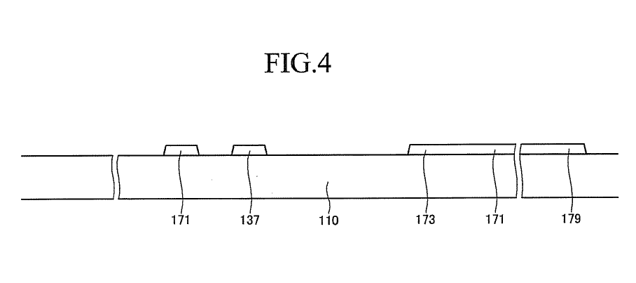

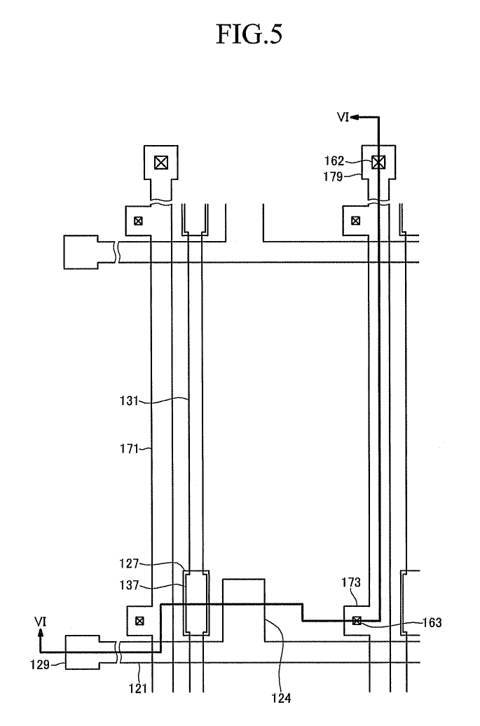

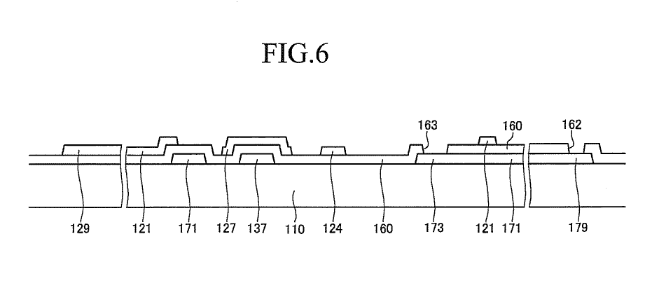

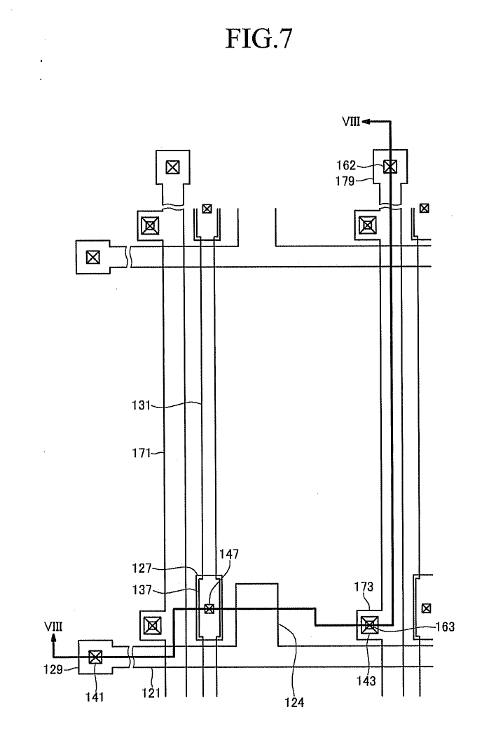

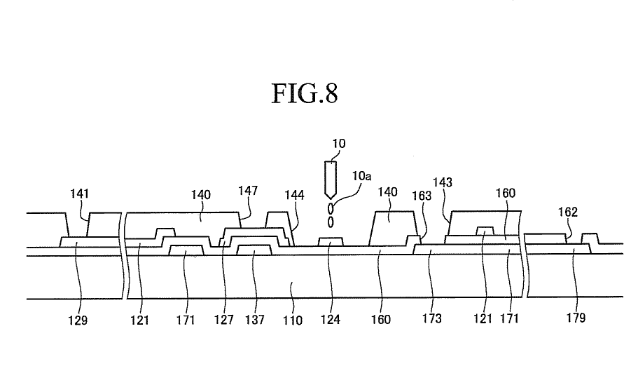

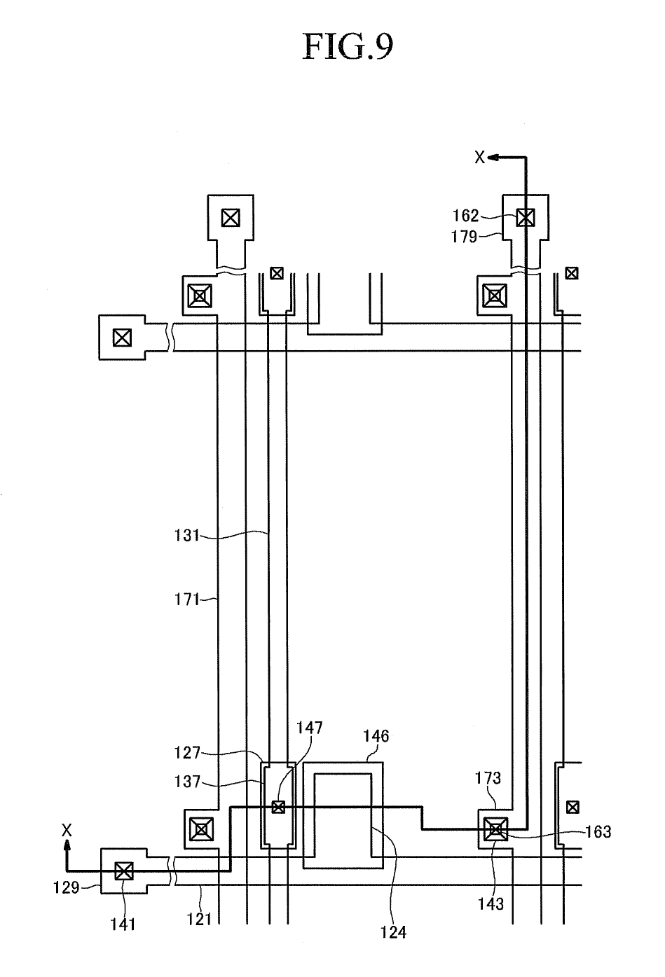

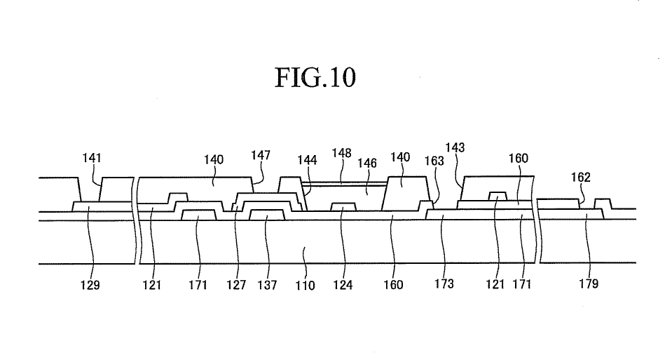

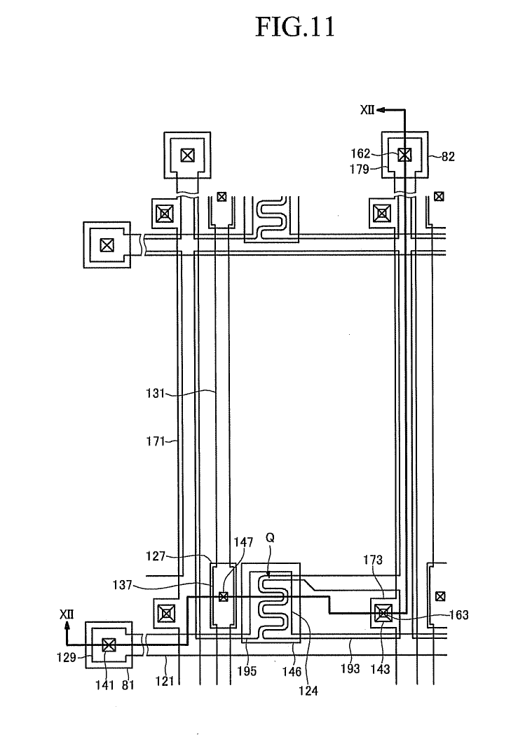

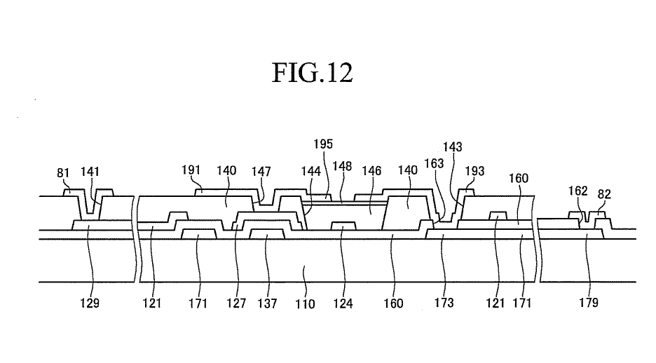

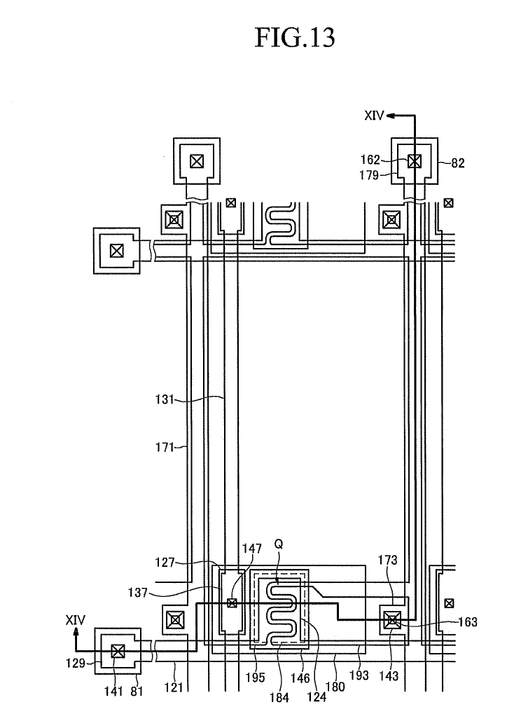

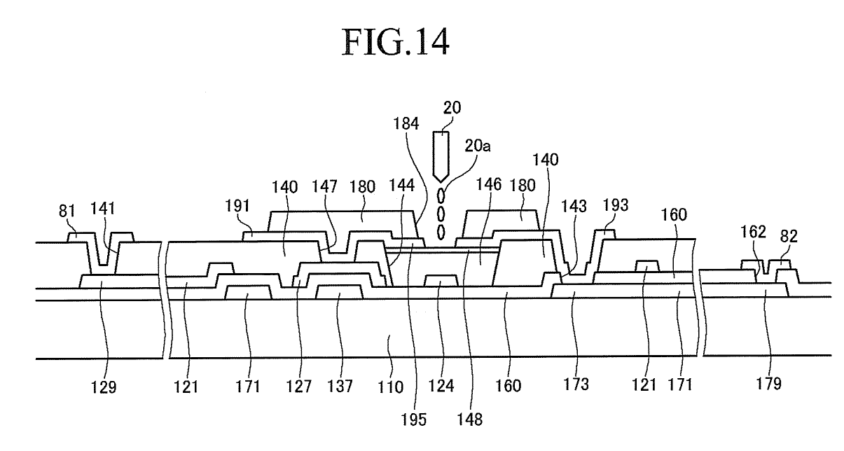

FIGS. 3, 5, 7, 9, 11 and 13 are layout views of the exemplary organic TFT array panel shown in FIGS. 1 and 2 during intermediate steps of an exemplary manufacturing method thereof according to an exemplary embodiment of the present invention, FIG. 4 is a sectional view of the exemplary TFT array panel shown in FIG. 3 taken along line IV-IV, FIG. 6 is a sectional view of the exemplary TFT array panel shown in FIG. 5 taken along line VI-VI, FIG. 8 is a sectional view of the exemplary TFT array panel shown in FIG. 7 taken along line VIII-VIII, FIG. 10 is a sectional view of the exemplary TFT array panel shown in FIG. 9 taken along line X-X, FIG. 12 is a sectional view of the exemplary TFT array panel shown in FIG. 11 taken along line XII-XII, and FIG. 14 is a sectional view of the exemplary TFT array panel shown in FIG. 13 taken along line XIV-XIV.

Referring to FIGS. 3 and 4, a conductive layer is deposited on a substrate 110 15 by using sputtering, etc., and is patterned by lithography and etched to form a plurality of data lines 171 including projections 173 and end portions 179, and a plurality of storage electrode lines 131 including a plurality of storage electrodes 137.

Referring to FIGS. 5 and 6, a lower interlayer insulating layer 160 having a plurality of contact holes 163 and 162 is deposited on the substrate 110 and the conductive pattern including the data lines 171 and storage electrode lines 131. The lower interlayer insulating layer 160 may be made of an inorganic material and may be deposited by chemical vapor deposition (“CVD”), etc., or may be made of an organic material and deposited by spin coating, for example. The lower interlayer insulating layer 160 may be made by an imprinting transfer etch process.

Next, a conductive layer, such as Al or an Al alloy, is deposited on lower interlayer insulating layer 160 on the substrate 110 by using sputtering, etc., and is patterned by lithography and etched to form a plurality of gate lines 121 including the gate electrodes 124 and end portions 129, and a plurality of storage capacitor conductors 127.

Referring to FIGS. 7 and 8, a photosensitive organic material is spin coated and patterned to form an upper interlayer insulating layer 140 having a plurality of openings 144 and a plurality of contact holes 143, 141, and 147 exposing the gate electrode 124, the projection 173, the end portion 129, and the storage capacitor conductor 127, respectively. Here, the organic material neighboring the end portions 179 of the data lines 171 is all removed.

Next, a system 10 for an ink-jet printing is arranged on or relative to the substrate 110 and an ink solvent 10a is sprayed in the openings 144. The ink solvent 10a includes a gate insulating material and a self assembly monolayer material.

The gate insulating material and the self assembly monolayer material may not be melted and not reacted with each other, and may be mixed uniformly or non-uniformly in the ink solvent 10a.

The gate insulator material is preferably made of, or from derivatives of, polyacryl, polystyrene, polyimide, polyvinyl alcohol, parylene, perfluorocyclobutane, perfluorovinylether, or benzocyclobutane (“BCB”).

The self assembly monolayer material may include one selected from 4-methoxybenzoic acid, 4-chlorobenzoyl chloride, 4-chlorobenzenesulfonyl chloride, 4-chlorophenyl dichlorophosphate, 4-fluorobenzenesulfonyl chloride, 2-bromo-4,6-difluorobenzene sulfonyl chloride, and 3-chloro-4-fluorobenzene sulfonyl chloride.

The gate insulating material and the self assembly monolayer material may be respectively manufactured into a liquefied state and mixed into the solvent, or may be manufactured in a solid state and melted in the solvent. When the gate insulating material and the self assembly monolayer material are respectively solids, the solid materials may be melted in the solvent such as benzene, toluene, and tetrahydrofuran, and a surfactant may be included to improve solubility. The surfactant may be preferably made of glycol ether, glycol ester, polyoxyethylene ether, polyoxyethylene ester, ethylene glycol, propylene glycol, glycerol, alkyl ethoxylate, diethanolamide, sorbitan esters, glyceryl esters, or lauryl dimethylamine oxide.

It is preferable that the content of the surfactant is in the range of about 0.001 to 0.5 weight percent in the total content of the ink solvent 10a.

Next, the sprayed solvent 10a is dried to form a plurality of gate insulators 146 and a plurality of self assembly monolayers 148 that are respectively separated with each layer, with the gate insulator 146 adjacent the gate electrode 124 and the insulating substrate 110 and the self assembly monolayer 148 on the gate insulator 146, as shown in FIGS. 9 and 10. Here, the material having larger specific gravity among the sprayed solvent 10a moves to the lower portion and the material having smaller specific gravity among the sprayed solvent 10a moves to the upper portion, such that the layer separation may be achieved. Also, the material having chemical attraction for the lower layer among the sprayed solvent 10a moves to the lower portion and the rest among the sprayed solvent 10a moves to the upper portion.

Referring to FIGS. 11 and 12, an amorphous ITO layer or IZO layer is deposited and patterned by lithography and wet etched with an etchant to form a plurality of source electrodes 193, a plurality of pixel electrodes 191 including drain electrodes 195, and a plurality of contact assistants 81 and 82.

The deposition of the amorphous ITO layer or IZO layer may be performed at a low temperature of about 25 to 100° C., and preferably at room temperature. The etchant for the amorphous ITO layer may include a weak alkaline etchant to reduce damage to the gate insulators 146 and the upper interlayer insulating layer 160 that are made of an organic material by heat or a chemical solvent.

Referring to FIGS. 13 and 14, a photosensitive organic material is coated and developed on the pixel electrodes 191 and source electrodes 193 to form a plurality of banks 180 including a plurality of openings 184 formed over the gate electrodes 124 and exposing a portion of the gate insulator 146 and self assembly monolayer 148.

Next, a system 20 for an inkjet printing is arranged on or relative to the substrate 110 and an ink solvent 20a is sprayed in the openings 184. The ink solvent 20a includes an organic semiconductor material and a passivation member material.

The organic semiconductor material and the passivation member material may not be melted and may not react with each other, and may be mixed uniformly or non-uniformly in the solvent 20a.

The organic semiconductor material may be made of, or from precursors of, pentacene, or is made of, or from derivatives of, tetrabenzoporphyrin, polyphenlenevinylene, polyfluorene, polythienylenevinylene, polythiophene, polythienothiophene, polyarylamine, and phthalocyanine, or is made of poly 3-hexylthiophene, metallized phthalocyanine or halogenated derivatives thereof, perylene tetracarboxylic dianhydride (“PTCDA”), naphthalene tetracarboxylic dianhydride (“NTCDA”), or their imide derivatives. Alternatively, the organic semiconductor islands 154 may also be made of perylene, coronene, or derivatives thereof with a substituent.

The passivation member material may be made of an insulating material such as a fluorine hydrocarbon compound, polyvinyl alcohol (“PVA”), polyvinyl pyrrolidone (“PVP”), polyethylene glycol, or derivatives thereof.

The organic semiconductor material and the passivation member material may be respectively manufactured into the liquefied state and mixed into the solvent, or may be manufactured in a solid state and melted in the solvent. When the organic semiconductor material and the passivation member material are respectively solid, the solid material may be melted in the solvent such as benzene, toluene and tetrahydrofuran, and a surfactant may be included to improve solubility. The surfactant may be preferably made of glycol ether, glycol ester, polyoxyethylene ether, polyoxyethylene ester, ethylene glycol, propylene glycol, glycerol, alkyl ethoxylate, diethanolamide, sorbitan esters, glyceryl esters, or lauryl dimethylamine oxide.

Next, the sprayed ink solvent 20a is dried to form a plurality of organic semiconductor islands 154 and a plurality of passivation members 186 that are respectively separated with each layer, as shown in FIGS. 1 and 2.

The ink solvent 20a may further include a self assembly monolayer material besides the organic semiconductor material, the passivation member material, and the surfactant. Here, the self assembly monolayers may be formed between the source and drain electrodes 193 and 195, and the organic semiconductor islands 154, which are exposed through the openings 184.

According to the embodiment of the present invention, the plurality of thin films are formed in one process by using the ink-jet printing, and accordingly the process cost and the process time may be remarkably decreased.

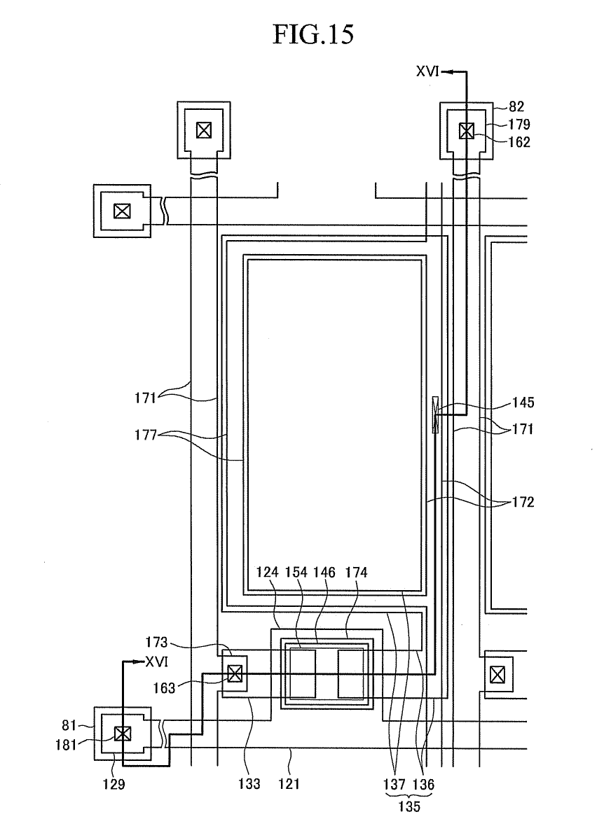

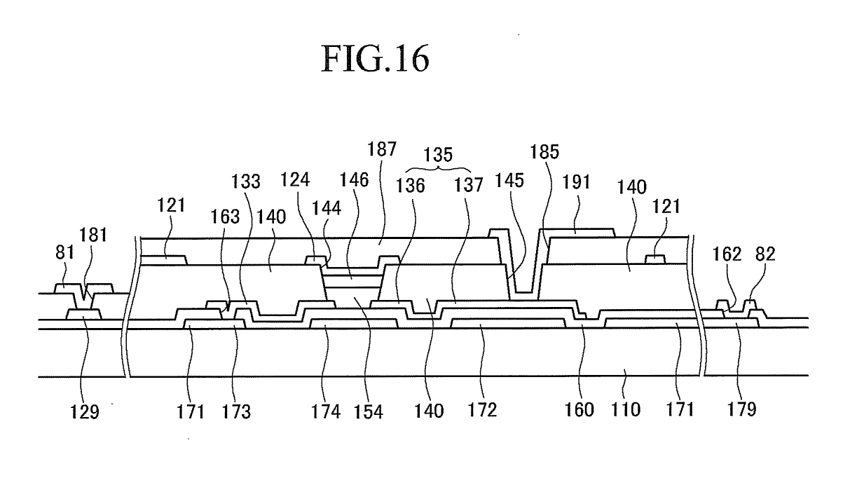

An OTFT array panel for a liquid crystal display (“LCD”) according to another exemplary embodiment of the present invention will be described in detail with reference to FIGS. 15 and 16.

FIG. 15 is a layout view of an exemplary organic TFT array panel according to another exemplary embodiment of the present invention, and FIG. 16 is a sectional view of the exemplary organic TFT array panel shown in FIG. 15 taken along line XVI-XVI.

As shown in FIGS. 15 and 16, a plurality of data lines 171, a plurality of storage electrode lines 172, and a plurality of light blocking layers 174 are formed on an insulating substrate 110 made of a material such as transparent glass, silicone, or plastic.

Each data line 171 includes a plurality of projections 173 protruding to a side towards an adjacent data line 171, and an end portion 179 having a large area for contact with another layer or an external driving circuit.

The storage electrode lines 172 extend substantially parallel to the data lines 171 and include a plurality of storage electrodes 177 expanding to the side for forming a ring shape or a frame shape within each pixel area. The light blocking layers 174 are separated from the data lines 171 and the storage electrode lines 172.

A lower interlayer insulating layer 160 is formed on the data lines 171, the storage electrode lines 172, the light blocking layers 174, and the exposed portions of the insulating substrate 110. The lower interlayer insulating layer 160 has a plurality of contact holes 162 exposing the end portions 179 of the data lines 171 and a plurality of contact holes 163 exposing the projections 173 of the data lines 171.

A plurality of source electrodes 133, a plurality of drain electrodes 135, and a plurality of contact assistants 82 are formed on the lower interlayer insulating layer 160.

The source electrodes 133 are connected to the projections 173 of the data lines 171 through the contact holes 163, and may have an island shape that at least partially overlaps the light blocking layer 174.

Each of drain electrodes 135 includes an electrode portion 136 that is disposed opposite the source electrode 133 on the light blocking layer 174 and a capacitor portion 137 that overlaps at least one portion of the storage electrode lines 172. Here, the electrode portions 136 disposed opposite the source electrodes 133 make a portion of a TFT and the capacitor portions 137 overlapping the storage electrode lines 172 reinforce a voltage storage capacity of a storage capacitor.

An upper interlayer insulating layer 140 is formed on the source electrodes 133, the drain electrodes 135, and exposed portions of the lower interlayer insulating layer 160, although the upper interlayer insulating layer 140 may be removed from the area of the end portions 179 of the data lines 171.

The upper interlayer insulating layer 140 has a plurality of openings 144 exposing the portions of the source electrodes 133 and the electrode portions 136 of the drain electrodes 135 that face each other, and the lower interlayer insulating layer 160 therebetween, and a plurality of contact holes 145 exposing the capacitor portions 137 of the drain electrodes 135.

A plurality of organic semiconductor islands 154 are formed in the openings 144 of the upper interlayer insulating layer 140, overlapping the light blocking layers 174, and a plurality of gate insulators 146 are formed on the organic semiconductor islands 154. The organic semiconductor islands 154 and the gate insulators 146 may be made of the material described in the previous embodiment.

A plurality of gate lines 121 including a plurality of gate electrodes 124 projecting upward towards adjacent gate lines 121 and an end portion 129 are formed on the gate insulators 146 and the upper interlayer insulating layer 140. As illustrated, the gate electrodes 124 completely overlap the organic semiconductor islands 154 and the light blocking layers 174.

A plurality of passivation members 187, such as a passivation layer, are formed on the gate lines 121 and on the exposed portions of the upper interlayer insulating layer 140. The passivation members 187 cover the end portions 129 for preventing adjacent end portions 129 from shorting to each other.

The passivation members 187 have a plurality of contact holes 185 and 181.

The contact holes 185 expose the capacitor portion 137 of the drain electrode 135 and are disposed on the contact holes 145 of the lower interlayer insulating layer 140, and the contact holes 181 expose the end portions 129 of the gate lines 121.

A plurality of pixel electrodes 191 and a plurality of contact assistants 81 are formed on the passivation layer 187. The pixel electrodes 191 are connected to the capacitor portions 137 of the drain electrodes 135 through the contact holes 185 and 145 and the contact assistants 81 are connected to the end portions 129 of the gate lines 121 through the contact holes 181, respectively.

In this embodiment, a top gate structure is described, where a gate electrode 124 is positioned over the organic semiconductor island 154 with respect to the substrate 110, and the upper interlayer insulating layer 140 has a function as a partition enclosing the organic semiconductor islands 154 and the gate insulators 146. Accordingly, one solvent including an organic semiconductor material and a gate insulator material may be sprayed to form the organic semiconductor islands 154 and the gate insulators 146 in the ink-jet printing process.

The gate insulator material and the organic semiconductor material are not melted and are not reacted with each other, and may include one material selected from the material described in the previous embodiment.

The gate insulator material and the organic semiconductor material may be respectively manufactured into a liquefied state and mixed into the solvent, or may be manufactured in a solid state and melted in the solvent.

When the gate insulator material and the organic semiconductor material are respectively solid, the solid material may be melted in the solvent such as benzene, toluene, and tetrahydrofuran, and a surfactant may be included to improve solubility. The surfactant may be preferably made of the material described in the previous embodiment.

Furthermore, the self assembly monolayers may be formed between the organic semiconductors and the gate insulators to improve the adhesion characteristics there between. Here, the method may further include forming a self assembly monolayer between the gate insulator and the organic semiconductor, wherein the self assembly monolayer is formed by an ink-jet printing process. A mixed solvent including at least two among the gate insulator material, the organic semiconductor material and the self assembly monolayer material is sprayed in the inkjet printing process.

As above-described, the plurality of thin films are formed in one process by using the inkjet printing, and accordingly the process cost and the process time may be remarkably decreased.

Although preferred and exemplary embodiments of the present invention have been described in detail hereinabove, it should be clearly understood that many variations and/or modifications of the basic inventive concepts herein taught that may appear to those skilled in the present art will still fall within the spirit and scope of the present invention, as defined in the appended claims.

What is claimed is:

1. A method for manufacturing a thin film transistor array panel, the method comprising:
forming a gate electrode;
forming a source electrode and a drain electrode opposing each other and separated from each other on the gate electrode;
forming a gate insulator on the gate electrode;
forming an organic semiconductor on the gate insulator; and
forming a passivation member covering the organic semiconductor,
wherein the source and drain electrodes contact the organic semiconductor, and an inljet printing process is used to form at least two among the gate insulator, the organic semiconductor, and the passivation member, and
wherein a mixed solvent including at least two among a gate insulator material, an organic semiconductor material, and a passivation member material is sprayed in the ink-jet printing process.

2. The method of claim 1, wherein the mixed solvent is insoluble.

3. The method of claim 1, wherein the mixed solvent is manufactured by melting at least two among the gate insulator material, the organic semiconductor material, and the passivation member material in a solvent.

4. The method of claim 3, wherein the mixed solvent includes a surfactant.

5. The method of claim 4, further comprising drying the mixed solvent to separate each layer of the at least two among the gate insulator, the organic semiconductor, and the passivation member after spraying the mixed solvent in the ink-jet printing process.

6. The method of claim 1, wherein the organic semiconductor material is made of, or from precursors of, pentacene, or is made of, or from derivatives of, tetrabenzoporphyrin, polyphenlenevinylene, polyfluorene, polythienylenevinylene, polythiophene, polythienothiophene, polyarylamine, and phthalocyanine, or is made of poly 3-hexylthiophene, metallized phthalocyanine or halogenated derivatives thereof, perylene tetracarboxylic dianhydride (“PTCDA”), naphthalene tetracarboxylic dianhydride (“NTCDA”), or their imide derivatives, or is made of perylene, coronene, or derivatives thereof with a substituent.

7. The method of claim 6, wherein the gate insulator material is made of, or from derivatives of, polyacryl, polystyrene, polyimide, polyvinyl alcohol, parylene, perfluorocyclobutane, perfluorovinylether, or benzocyclobutane (“BCB”).

8. The method of claim 7, wherein the passivation member material is made of an insulating material such as a fluorine hydrocarbon compound, polyvinyl alcohol (“PVA”), polyvinyl pyrrolidone (“PVP”), polyethylene glycol, and derivatives thereof.

9. The method of claim 1, further comprising forming a self assembly monolayer between the gate insulator and the organic semiconductor, wherein the self assembly monolayer is formed by an ink-jet printing process, and a mixed solvent including at least two among the gate insulator material, the organic semiconductor material, and self assembly monolayer material is sprayed in the ink-jet printing process.

10. The method of claim 9, wherein the self assembly monolayer material includes one selected from 4-methoxybenzoic acid, 4-chlorobenzoyl chloride, 4-chlorobenzenesulfonyl chloride, 4-chlorophenyl dichlorophosphate, 4-fluorobenzenesulfonyl chloride, 2-bromo-4,6-difluorobenzene sulfonyl chloride, and 3-chloro-4-fluorobenzene sulfonyl chloride.

11. A method for manufacturing a thin film transistor array panel, the method comprising:
forming a source electrode and a drain electrode opposing each other and separated from each other;
forming an organic semiconductor island on and between the source and drain electrodes and forming a gate insulator on the organic semiconductor island using an ink-jet printing process to form the organic semiconductor island and the gate insulator, wherein a mixed solvent including both gate insulator material and organic semiconductor material is sprayed in the inljet printing process on and between the source and drain electrodes; and, forming a gate electrode on the gate insulator.

12. The method of claim 11, further comprising drying the mixed solvent subsequent the inkjet printing process to separate the gate insulator from the organic semiconductor island.

13. A method for manufacturing a thin film transistor array panel, the thin film transistor array panel having a plurality of thin films including a gate insulator, an organic semiconductor, and a passivation member, the method comprising:
forming at least two of the plurality of thin films simultaneously using an ink-jet printing process, wherein a mixed solvent including at least two among a gate insulator material, an organic semiconductor material, and a passivation member material is sprayed in the ink-jet printing process.

14. The method of claim 13, wherein the at least two of the plurality of thin films simultaneously formed includes the organic semiconductor and the passivation member, the method further comprising drying the mixed solvent subsequent the ink-jet printing process to separate the organic semiconductor from the passivation member.

15. The method of claim 13, wherein the at least two of the plurality of thin films simultaneously formed includes the organic semiconductor and the gate insulator, the method further comprising drying the mixed solvent subsequent the ink-jet printing process to separate the organic semiconductor from the gate insulator.

16. The method of claim 13, wherein the mixed solvent further includes a surfactant.

17. The method of claim 13, wherein spraying the mixed solvent in the ink-jet printing process includes spraying the mixed solvent on and between source and drain electrodes of the thin film transistor array panel.
